(19) United States
(12) Patent Application Publication
(10) Pub. No.: US 2013/0312822 A1
(43) Pub. Date: Nov. 28, 2013

(54) SOLAR-CELL DEVICE

(71) Applicant: INDUSTRIAL TECHNOLOGY RESEARCH INSTITUTE, (US)

(72) Inventors: Hung-Yi LIN, Hsinchu City (TW); Ta-Hsin CHOU, Hsinchu City (TW); Jen-Hui TSAI, Hsinchu City (TW); Chia-Chen HSU, Chiayi County (TW); Jian-Hung LIN, Chiayi County (TW); Hung-Chih KAN, Chiayi City (TW)

(73) Assignee: INDUSTRIAL TECHNOLOGY RESEARCH INSTITUTE, Hsinchu (TW)

(21) Appl. No.: 13/761,278

(22) Filed: Feb. 7, 2013

(30) Foreign Application Priority Data
May 24, 2012 (TW) 101118468

(51) Int. Cl. H01L 31/0352; H01L 31/0224

(52) U.S. Cl. CPC H01L 31/035281; H01L 31/022425
USPC 136/256

(57) ABSTRACT

The disclosure provides a solar-cell device, including a substrate, a first electrode layer comprising a first two-dimensional periodic structure disposed on the substrate, a first light conversion layer disposed on the first two-dimensional periodic structure, a second light conversion layer disposed on the first light conversion layer; and a second electrode layer disposed on the second light conversion layer.

### CROSS-REFERENCE TO RELATED APPLICATION

This application claims priority of Taiwan Patent Application No 101118468, filed on May, 24, 2012, the entirety of which is incorporated by reference herein.

### BACKGROUND

1. Technical Field

This disclosure generally relates to an optical electrical device and more particularly to a solar device.

2. Description of the Related Art

Solar cells have become an important research focus. Solar cells can be disposed on buildings such as houses, and movable apparatuses such as cars, indoors, or on portable electric devices, to convert light into electrical power. In recent years, many science companies are engaged in research and production of Cu—In—Ga—Se (CIGS) solar cells. Modular CIGS solar cells which have a conversion efficiency higher than 10% have been developed, and the cost thereof is lower than the silicon solar cells. Therefore, it is suspected that market share of CIGS solar cells should be increased.

In the year 2008, the National Renewable Energy Lab (NREL) announced a CIGS solar cell having a conversion efficiency reaching 19.9%, with a fill factor (FF) of 81.2 and a GIGS layer 2.2 μm thick. ZSW have developed a CIGS solar cell having a conversion efficiency reaching 20.3%, with an area of 0.5 mm² and CIGS layer thickness of 4 μm.

According to the above description, the thickness of the GIGS layer of a GIGS solar cell is generally required to be greater than 2 μm if the solar cell is going to have a good conversion efficiency. The CIGS layer of a CIGS solar cell is formed by co-evaporation of Cu, In, Ga and Se, wherein the indium (In) is especially unusual and the CIGS material is very expensive. Therefore, a means of reducing the thickness of the CIGS layer of a CIGS solar cell and maintaining good enough device performance is an important research focus.

### SUMMARY

The disclosure provides a solar-cell device, comprising a substrate, a first electrode layer comprising a first two-dimensional periodic structure disposed on the substrate, a first light conversion layer disposed on the first two-dimensional periodic structure, a second light conversion layer disposed on the first light conversion layer; and a second electrode layer disposed on the second light conversion layer.

### BRIEF DESCRIPTION OF DRAWINGS

The disclosure can be more fully understood by reading the subsequent detailed description and examples with references made to the accompanying drawings, wherein,

FIG. 1 shows a cross-sectional view of a solar cell of an embodiment of the disclosure.

FIG. 2A shows a three-dimensional view of a solar cell of an embodiment of the disclosure.

FIG. 2B shows a three-dimensional view of a solar cell of another embodiment of the disclosure.

FIG. 3 shows a cross-sectional view of a solar cell of an embodiment of the disclosure.

FIG. 4 shows a cross-sectional view of a solar cell of an embodiment of the disclosure.

FIG. 5 shows a cross-sectional view of a solar cell of an embodiment of the disclosure.

FIG. 6A shows curves with current density as a function of incident angle to compare the performance of the first, second, and third conditions of the disclosure.

FIG. 6B shows curves with enhancement factor as a function of incident angles to compare the enhancement factor with the first condition compared to the second condition, and with the first condition compared to the third condition.

FIG. 6C shows curves with current density as a function of incident angle to compare the performance of the fourth, fifth, and sixth conditions of the disclosure.

FIG. 6D shows curves with enhancement factor as a function of incident angles to compare the enhancement factor with the fourth condition compared to the fifth condition, and with the fourth condition compared to the sixth condition.

### DETAILED DESCRIPTION

It is understood that specific embodiments are provided as examples to teach the broader inventive concept, and one of ordinary skill in the art can easily apply the teaching of the present disclosure to other methods or apparatus. The following discussion is only used to illustrate the application, not limit the application.

The disclosure forms a subwavelength periodical nano structure in a CIGS solar cell. Due to the high refractive index in the wavelength range of visible light, i.e. 500 nm˜1 μm, CIGS material can be a wave-guide layer. The disclosure sets a two-dimensional periodic structure. Incident light going into the solar cell through the periodic structure can use a light trapping effect to increase light paths in the CIGS solar cell, so that the light absorption thereof is increased. The performance of the CIGS solar cell can therefore be increased, and the thickness of the CIGS material can be reduced.

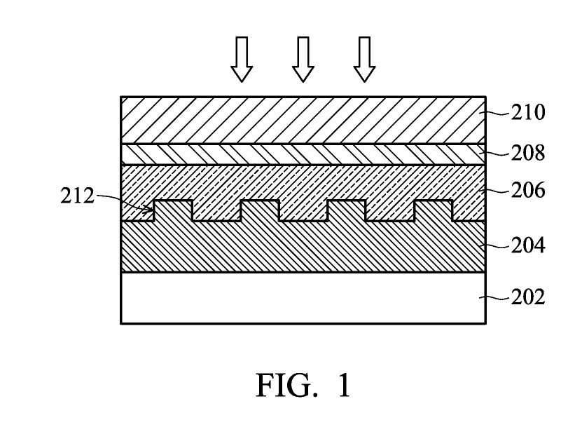

A solar cell of an embodiment of the disclosure is illustrated in accordance with FIG. 1. In the embodiment, the solar cell can be a CIGS solar cell. Referring to FIG. 1, a substrate 202 is provided, a first electrode layer 204 comprising a first two-dimensional periodic structure 212 is disposed on the substrate 202, a first light conversion layer is disposed on the first two-dimensional periodic structure 212, a second light conversion layer 208 disposed on the first light conversion layer 206, a second electrode layer 210 is disposed on the second light conversion layer 208. Specifically, the second electrode layer 210 is a light incidence side of the solar-cell device, and the substrate 202 is a light output side of the solar-cell device. The substrate 202 can comprise ceramic materials, semiconductor materials (such as silicon), glass, aluminum, plastic materials, metal or the like. The thickness of the substrate 202 can be 1000 nm˜4000 nm. The first electrode layer 204 can be Mo, Al, Cu, Ti, Au, Pt, Ag, Cr or the like. The thickness of the first electrode layer 204 can be 500 nm˜1000 nm. The first light conversion layer 206 and the second light conversion layer 208 can have different types of conductivity. For example, the first light conversion layer 206 can be p type, and the second light conversion layer 208 can be n type. Alternatively, the first light conversion layer 206 can be n type, and the second light conversion layer 208 can be p type. Thus, a pn junction can be formed between the first light conversion layer 206 and the second light conversion layer 208. The first light conversion layer 206 can be a CIGS material layer, comprising Cu, In/Ga and Se, a CIS material layer, comprising Cu, In and Se, a CGS material layer, comprising Cu, Ga, Se, or the like, or combinations thereof. The second light conversion layer 208 can be CdS. In an embodiment, the first light conversion layer 206 can be a CIGS material layer, comprising Cu, In/Ga and Se, and the second light conversion layer 208 can be CdS. The thickness of the first light conversion layer 206 can be 500 nm˜2000 nm, and the thickness of the second light conversion layer 208 can be 50 nm˜100 nm. The second electrode layer 210 can be a transparent electrode layer, such as indium tin oxide (ITO), indium zinc oxide (IZO), gallium zinc oxide (GAZO), ZnMgO, SnO₂ or the like. The thickness of the second electrode layer 210 can be 500 nm˜1000 nm.

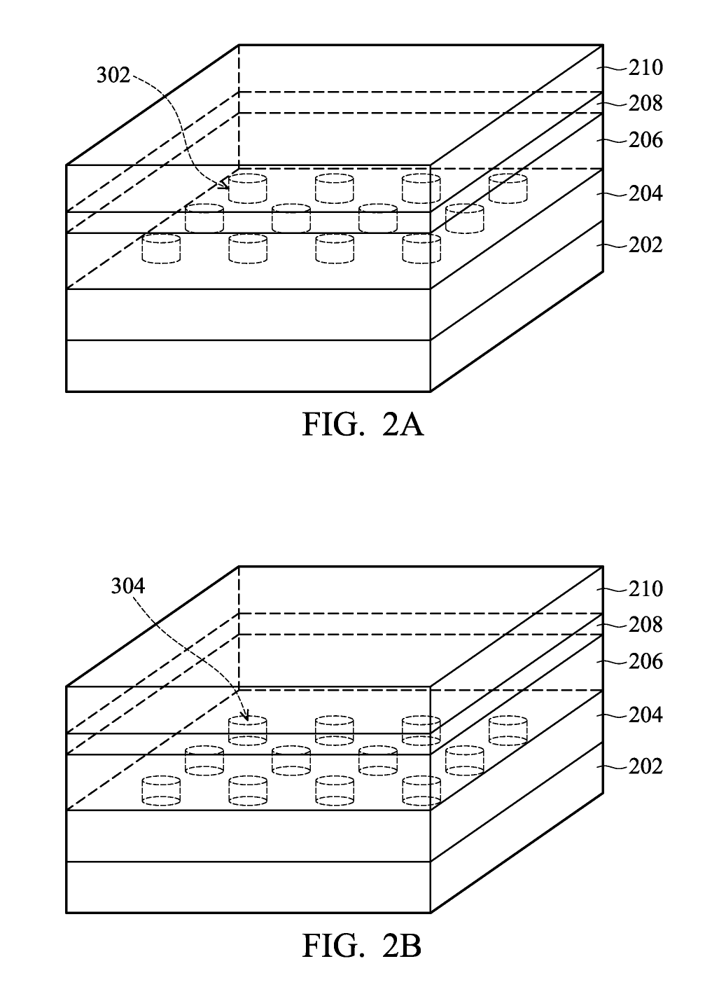

It should be noted that the embodiment sets a periodic structure between the first electrode layer 204 and the first light transformation layer 206, using the guided-mode resonant effect and diffusion effect from the periodic structure to generate a light trapping effect for increasing light paths in the solar cell. Therefore, the photoelectric conversion efficiency of the solar cell can be increased. The embodiment can use a two-dimensional periodic structure, such as the circular column array structure 302 as shown in FIG. 2A, or the circular hole array structure 304 as shown in FIG. 2B, for the solar cell to effectively increase its conversion efficiency for light at various incident angles. However, the disclosure is not limited the two-dimensional periodic structure shown in FIG. 2A or FIG. 2B. The disclosure can use other two-dimensional periodic structures, such as a square column array structure, a hexagonal column array structure, an octagonal column array structure, a square hole array structure, a hexagonal hole array structure, an octagonal hole array structure or a two-dimensional grating structure.

An embodiment of the disclosure can use E-beam lithography technology, focused ion beam technology, laser beam, nanoimprint technology or the like to pattern the first electrode layer 204 for forming a two-dimensional periodic structure. In an embodiment of the disclosure, the column array structure 302 can have a period of about 100 nm˜1600 nm, a height of about 50˜300 nm, and a filling factor (r/a, r is radius of the structure, and a is period of the structure) of about 0.05˜0.5. The circular hole array structure 304 can have a period of about 100 nm˜1600 nm, a height of about 50˜300 nm, and a filling factor (r/a, r is radius of the structure, and a is period of the structure) of about 0.05˜0.5.

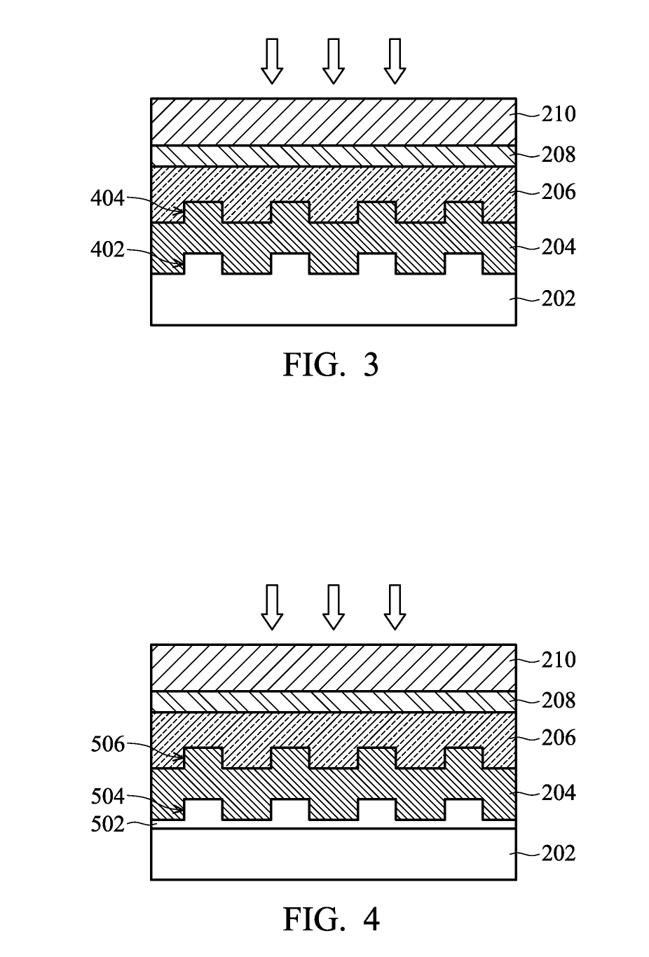

The embodiment is not limited to forming a periodic structure between the first electrode layer 204 and the first light transformation layer 206. Referring to FIG. 3, another embodiment of the disclosure can pattern a light incidence surface of the substrate 202 to form a periodic structure 402, and the first electrode layer 204 overlying the substrate 202 can form a like periodic structure 404 according to the periodic structure 402 of the substrate 202. As shown in FIG. 3, according a structural aspect of the embodiment of the disclosure, a substrate 202 comprising a first two-dimensional periodic structure 402 is provided, a first electrode layer 204 comprising a second two-dimensional periodic structure 404 is disposed on the substrate 202, a first light conversion layer 206 is disposed on the second two-dimensional periodic structure 506, a second light conversion layer 208 is disposed on the first light conversion layer 206, and a second electrode layer 210 is disposed on the second light conversion layer 208. Specifically, the second electrode layer 210 is a light incidence side of the solar-cell device, and the substrate 202 is a light output side of the solar-cell device. The embodiment can use E-beam lithography technology, focused ion beam technology, laser beam, nanoimprint technology or the like to pattern the substrate 202 for forming a two-dimensional periodic structure. The periodic structure 402 of the substrate 202 and the periodic structure 404 of the first electrode layer 204 can be a circular column array structure, a square column array structure, a hexagonal column array structure, an octagonal column array structure, a circular hole array structure, a square hole array structure, a hexagonal hole array structure, an octagonal hole array structure or a two-dimensional grating structure.

Referring to FIG. 4, another embodiment of the disclosure can form a polymer layer 502 on the substrate 202 and pattern a light incidence surface of the polymer layer 502 to form a periodic structure 504 using a method such as nanoimprinting. The first electrode layer 204 overlying the substrate 202 can form a like periodic structure 506 according to the periodic structure 504 of the polymer layer 502 on substrate 202. As shown in FIG. 4, according a structural aspect of the embodiment of the disclosure, a substrate 202 is provided, a polymer layer 502 comprising a first two-dimensional periodic structure 504 is disposed on the substrate 202, a first electrode layer 204 comprising a second two-dimensional periodic structure 404 is disposed on the polymer layer 502, a first light conversion layer 206 is disposed on the second two-dimensional periodic structure 506, a second light conversion layer 208 is disposed on the first light conversion layer 206, and a second electrode layer 210 is disposed on the second light conversion layer 208. Specifically, the second electrode layer 210 is a light incidence side of the solar-cell device, and the substrate 202 is a light output side of the solar-cell device. The periodic structure 504 and 506 can be circular column array structure, a square column array structure, a hexagonal column array structure, an octagonal column array structure, a circular hole array structure, a square hole array structure, a hexagonal hole array structure, an octagonal hole array structure or a two-dimensional grating structure.

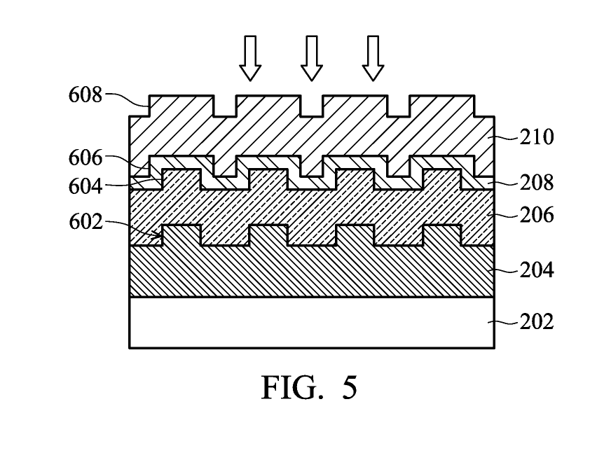

Referring to FIG. 5, another embodiment of the disclosure can increase the height and depth of the periodic structure 602 on the first electrode layer 204, and adjust the thickness of the structure formed thereafter for the first light conversion layer 206, the second light conversion layer 208, and the second electrode layer 210 overlying the first electrode layer 204 to form periodic structures 604, 606, 608 as with the periodic structure 602 of the first electrode layer 204. As shown in FIG. 5, according a structural aspect of the embodiment of the disclosure, a substrate 202 is provided, a first electrode layer 204 comprising a first two-dimensional periodic structure 602 is disposed on the substrate 202, a first light conversion layer 206 comprising a second two-dimensional periodic structure 604 is disposed on the first electrode layer 204, a second light conversion layer 208 comprising a third two-dimensional periodic structure 606 is disposed on the first light conversion layer 206, and a second electrode layer 210 comprising a fourth two-dimensional periodic structure 608 is disposed on the second light conversion layer 208. Specifically, the second electrode layer 210 is a light incidence side of the solar-cell device, and the substrate 202 is a light output side of the solar-cell device. In the embodiment, the periodic structure 602 of the first electrode layer 204 can have a period of about 100 nm˜1000 nm, height (or depth) of about 50˜300 nm, and filling factor (r/a) of about 0.1˜0.45. The thickness of the first light conversion layer 206 can be 500 nm˜2000 nm. The thickness of the second light conversion layer 208 can be 50 nm˜100 nm. The thickness of the second electrode layer 210 can be 500 nm˜1000 nm.

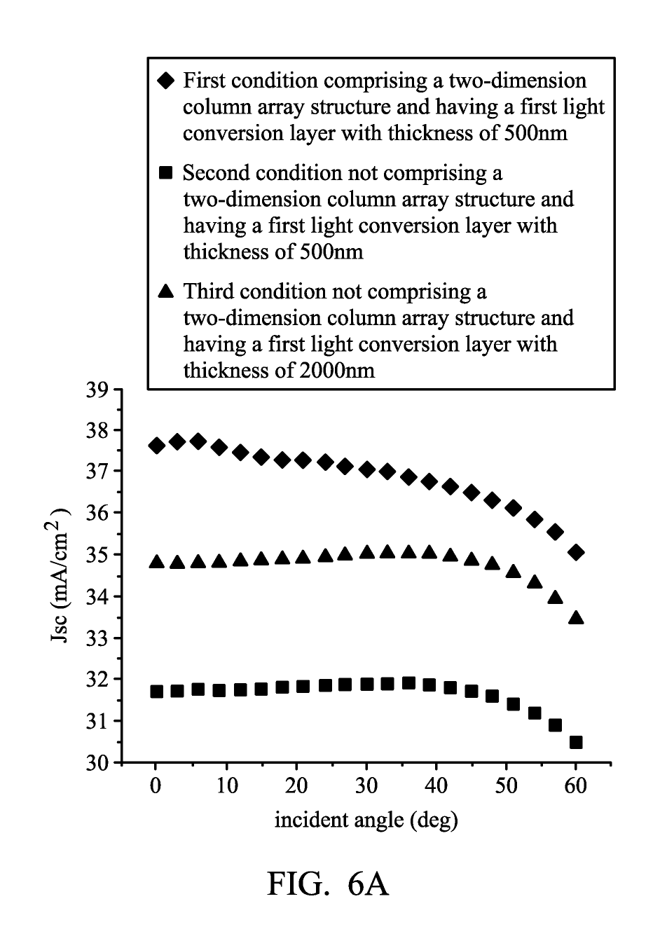

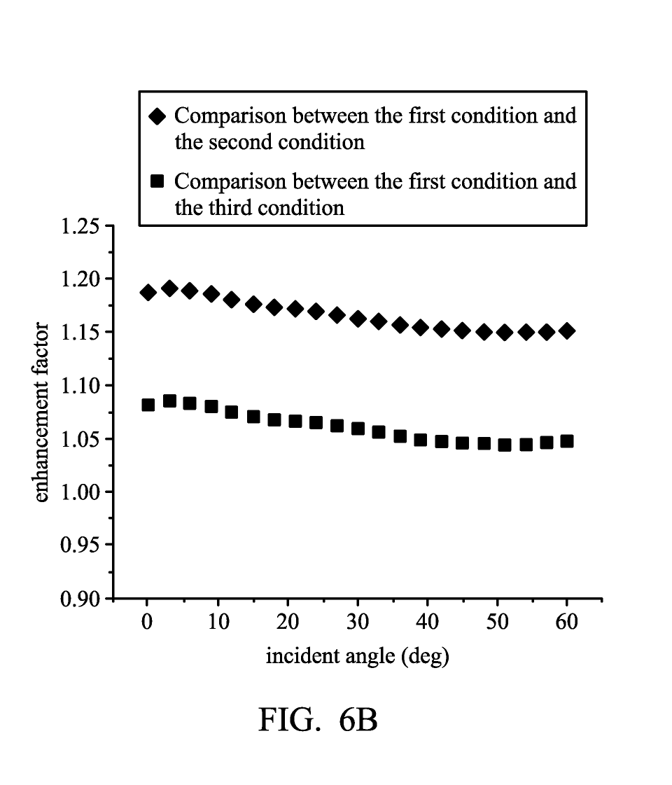

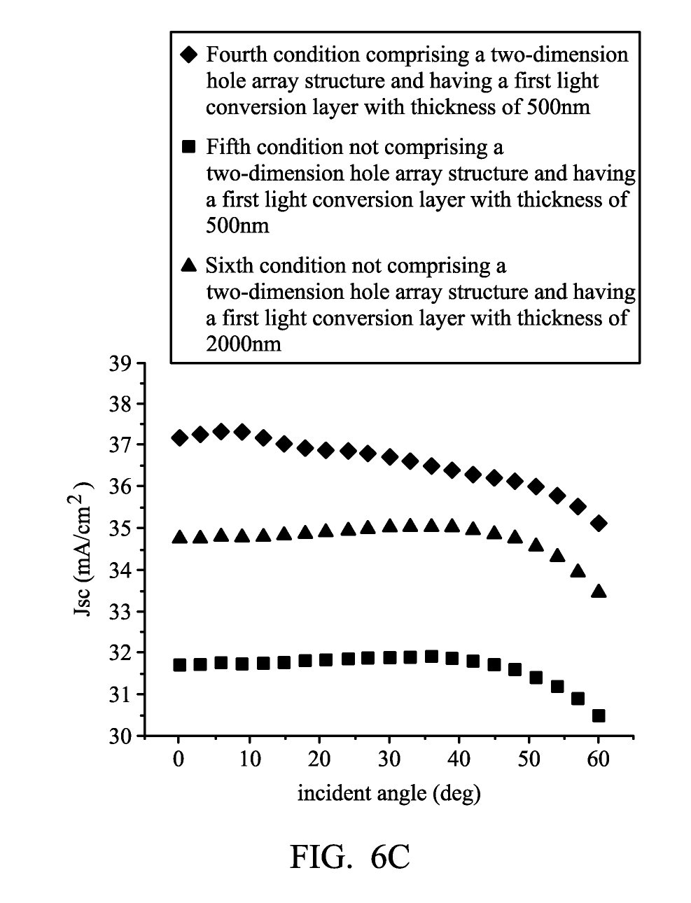

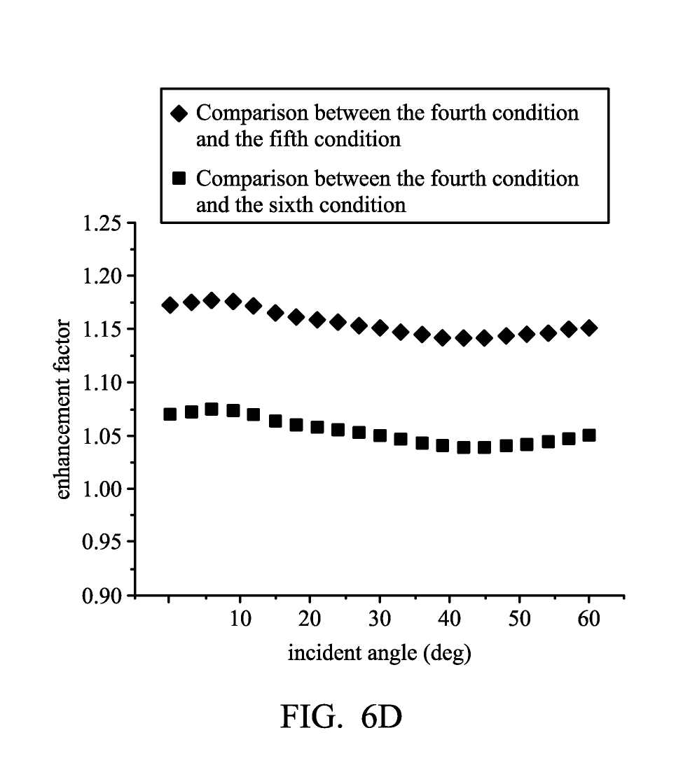

FIG. 6A shows curves with current density as a function of incident angle to compare performance over three conditions, wherein the first condition comprises a two-dimensional column array structure and has a first light conversion layer with a thickness of 500 nm, the second condition does not comprise a two-dimensional column array structure but has a first light conversion layer with a thickness of 500 nm, and the third condition does not comprise a two-dimensional column array structure but has a first light conversion layer with a thickness of 2000 nm. As shown in FIG. 6A, the first condition comprising a two-dimensional column array structure and having a first light conversion layer with a thickness of 500 nm has the greatest current density for light at various incident angles. FIG. 6B shows curves with enhancement factor as a function of incident angle to compare the enhancement factor of the first condition compared to the second condition, and with the first condition compared to the third condition. As shown in FIG. 6B, the first condition comprises a two-dimensional column array structure and has a first light conversion layer with a thickness of 500 nm, which is an example of the disclosure, and it has an enhancement factor over 15% better than that of the second condition not comprising a two-dimensional column array structure and having a first light conversion layer with a thickness of 500 nm for light at various incident angles. The first condition comprising a two-dimensional column array structure and having a first light conversion layer with a thickness of 500 nm, which is an example of the disclosure, has an enhancement factor over 4% better than that of the third condition not comprising a two-dimensional column array structure and having a first light conversion layer with a thickness of 2000 nm for light at various incident angles.

FIG. 6C shows curves with current density as a function of incident angle to compare performance under three conditions. The fourth condition comprises a two-dimensional hole array structure and has a first light conversion layer with a thickness of 500 nm. The fifth condition does not comprise a two-dimensional hole array structure but has a first light conversion layer with a thickness of 500 nm. The sixth condition does not comprise a two-dimensional hole array structure but has a first light conversion layer with a thickness of 2000 nm. As shown in FIG. 6C, the first condition comprising a two-dimensional hole array structure and having a first light conversion layer with a thickness of 500 nm has the greatest current density for light at various incident angles. FIG. 6D shows curves with enhancement factor as a function of incident angle to compare the enhancement factors, with the fourth condition compared to fifth the condition, and with the fourth condition compared to the sixth condition. As shown in FIG. 6D, the fourth condition comprising a two-dimensional hole array structure and having a first light conversion layer with a thickness of 500 nm, which is an example of the disclosure, has an enhancement factor over 15% better than the fifth condition not comprising a two-dimensional hole array structure and having a first light conversion layer with a thickness of 500 nm for light at various incident angles. The fourth condition comprising a two-dimensional hole array structure and having a first light conversion layer with a thickness of 500 nm has an enhancement factor over 4% better than the sixth condition not comprising a two-dimensional hole array structure and having a first light conversion layer with a thickness of 2000 nm for light at various incident angles.

According to the experimental results described above, the formation of a two-dimensional periodic structure in a CIGS solar cell increases the light conversion efficiency for light at various incident angles.

While the disclosure has been described by way of example and in terms of the preferred embodiments, it is to be understood that the disclosure is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar-cell device, comprising:
a substrate;
a first electrode layer comprising a first two-dimensional periodic structure disposed on the substrate;
a first light conversion layer disposed on the first two-dimensional periodic structure;
a second light conversion layer disposed on the first light conversion layer; and
a second electrode layer disposed on the second light conversion layer,

2. The solar-cell device as claimed in claim 1, wherein the first light conversion layer is a CIGS material layer, comprising Cu, In/Ga and Se, a CIS material layer, comprising Cu, In and Se, or a CGS material layer, comprising Cu, Ga and Se.

3. The solar-cell device as claimed in claim 2, wherein the first light conversion layer is a CIGS material layer, comprising Cu, In/Ga and Se.

4. The solar-cell device as claimed in claim 1, wherein the second light conversion layer comprises CdS.

5. The solar-cell device as claimed in claim 1, wherein the first electrode layer comprises Mo.

6. The solar-cell device as claimed in claim 1, wherein a light incidence surface of the substrate comprises a second two-dimensional periodic structure, wherein the second two-dimensional periodic structure has a contour like that of the first two-dimensional periodic structure of the first electrode layer.

7. The solar-cell device as claimed in claim 1, further comprising a polymer layer between the substrate and the first electrode layer, wherein a light incidence surface of the polymer layer comprises a third two-dimensional periodic structure, wherein the third two-dimensional periodic structure has a contour like that of the first two-dimensional periodic structure.

8. The solar-cell device as claimed in claim 1, wherein a light incidence surface of the first light conversion layer comprises a fourth two-dimensional periodic structure, wherein the fourth two-dimensional periodic structure has a contour like that of the first two-dimensional periodic structure of the first electrode layer.

9. The solar-cell device as claimed in claim 1, wherein a light incidence surface of the second light conversion layer comprises a fifth two-dimensional periodic structure, wherein the fifth two-dimensional periodic structure has a contour like that of the first two-dimensional periodic structure of the first electrode layer.

10. The solar-cell device as claimed in claim 1, wherein a light incidence surface of the second electrode layer comprises a sixth two-dimensional periodic structure, wherein the sixth two-dimensional periodic structure has a contour like that of the first two-dimensional periodic structure of the first electrode layer.

11. The solar-cell device as claimed in claim 1, wherein the first two-dimensional periodic structure comprises circular column array structure, a square column array structure, a hexagonal column array structure, an octagonal column array structure, a circular hole array structure, a square hole array structure, a hexagonal hole array structure, an octagonal hole array structure, or a two-dimensional grating structure.

12. The solar-cell device as claimed in claim 11, wherein the circular column array structure has a period of about 100 nm˜1600 nm, a height of about 50˜300 nm, and a filling factor of about 0.05˜0.5.

13. The solar-cell device as claimed in claim 11, wherein the circular hole array structure has a period of about 100 nm˜1600 nm, a height of about 50˜300 nm, and a filling factor of about 0.05˜0.5.

14. The solar-cell device as claimed in claim 11, wherein the second electrode layer is a light incidence side of the solar-cell device, and the substrate is a light output side of the solar-cell device.
